(19) United States
(12) Patent Application Publication
(10) Pub. No.: US 2023/0179921 A1
(43) Pub. Date: Jun. 8, 2023

(54) Speaker

(71) Applicant: AAC Microtech (Changzhou) Co., Ltd., Changzhou City, (CN)

(72) Inventors: Wei Song, Shenzhen (CN); Xin Jin, Shenzhen (CN); Fan Zhang, Shenzhen (CN)

(21) Appl. No.: 17/562,036

(22) Filed: Dec. 27, 2021

(30) Foreign Application Priority Data
Dec. 3, 2021 (CN) 202123024536.1

(51) Int. Cl. H04R 9/06; H04R 9/02; H04R 9/04; H05K 1/11

(52) U.S. Cl. CPC H04R 9/06; H04R 9/027; H04R 9/045; H05K 1/118; H04R 2400/11; H05K 2201/10083

(57) ABSTRACT

The present disclosure discloses a speaker including a frame, a vibration system, and a magnetic circuit system. The vibration system includes an upper diaphragm, an elastic supporting member, a skeleton, and a voice coil. The upper diaphragm includes a suspension, an inner fixing part fixed to the skeleton, and an outer fixing part fixed to the frame. The skeleton includes a main body part and an extension part. The elastic supporting member is fixed to the extension part. The main body part together with the upper diaphragm separates an internal space of the speaker from an outside space. Compared with the related art, the speaker disclosed by the present disclosure has a better acoustic performance.

### FIELD OF THE PRESENT DISCLOSURE

The present disclosure relates to electroacoustic transducers, in particular to a speaker.

### DESCRIPTION OF RELATED ART

A speaker in the related art includes a frame, a vibration system and a magnetic circuit system fixed to the frame. The vibration system includes a dome, an upper diaphragm around the dome and spaced apart from the dome, an elastic supporting member locating at a side of the upper diaphragm close to the magnetic circuit system and spaced apart from the upper diaphragm, a skeleton, and a voice coil fixed to the skeleton. The skeleton includes a first part with a through hole connecting the dome and the upper diaphragm, and a second part bending and extending from the first part in a direction close to the elastic supporting member for connecting with the elastic supporting member. The dome is attached to the first part and covers the through hole of the first part. The dome together with the first part of the skeleton and the upper diaphragm separates an internal space of the speaker from an outside space.

A height of a space above the magnetic circuit system occupied by the vibration system is the sum of a thickness of the dome and a thickness of the first part of the skeleton, which causes the vibration system to occupy excessive space above the magnetic circuit system, thereby limiting a size of the magnetic circuit system. Thus, it is harmful to raise acoustic performances of the speaker. In addition, the concentricity of the dome and the frame affects the symmetry of the vibration system. The poor concentricity causes the vibration system to sway, thereby affecting acoustic performances of the speaker. While, the requirement of the concentricity brings difficulties of manufacturing the vibration system.

Thus, it is necessary to provide a novel speaker to solve the problem.

### SUMMARY

An objective of the present disclosure is to provide a speaker which has a better acoustic performance.

In order to achieve the objective mentioned above, the present disclosure discloses a speaker including a frame, a vibration system fixed to the frame, and a magnetic circuit system fixed to the frame. The vibration system includes an upper diaphragm, an elastic supporting member locating at a side of the upper diaphragm close to the magnetic circuit system and spaced apart from the upper diaphragm, a skeleton for connecting the upper diaphragm and the elastic supporting member, and a voice coil fixed to the skeleton. The upper diaphragm includes a suspension, an inner fixing part extending from an inner periphery of the suspension, and an outer fixing part extending from an outer periphery of the suspension. The inner fixing part of the upper diaphragm is fixed to the skeleton, and the outer fixing part of the upper diaphragm is fixed to the frame. The skeleton includes a main body part, and an extension part bending and extending from the main body part in a direction close to the elastic supporting member. The elastic supporting member is fixed to the extension part of the skeleton. The main body part together with the upper diaphragm separates an internal space of the speaker from an outside space. Compared with the related art, the main body part together with the upper diaphragm separates an internal space of the speaker from an outside space. The main body part can serve as a dome, thus an original dome can be omitted. In this way, the height of the space above the magnetic circuit system occupied by the vibration system is only the thickness of the skeleton, thereby releasing the height of the space above the magnetic circuit system occupied by the original dome, which can be used for increasing the size of the magnetic circuit system. While it avoids effects of the concentricity of the original dome and the skeleton on the vibration system and optimizes the sway of the vibration system. Thus, it is beneficial for improving acoustic performances of the speaker. In addition, it saves the cost of the original dome and reduces difficulties of manufacturing the vibration system.

Further, the main body part includes a lower surface close to the magnetic circuit system, and an upper surface opposite to the lower surface. The inner fixing part is fixed to the upper surface, and the voice coil is fixed to the lower surface.

Further, the main body part is provided with a protrusion protruding in a direction away from the magnetic circuit system.

Further, the main body part includes a first planar portion, a connecting portion bending and extending from the first planar portion in a direction close to the magnetic circuit system, and a second planar portion bending and extending from the connecting portion in a direction away from the first planar portion. The second planar portion is parallel with the first planar portion. The voice coil is fixed to the second planar portion. The first planar portion together with the connecting portion forms the protrusion.

Further, an outer edge of an orthographic projection of the protrusion along a vibration direction of the vibration system coincides with an inner edge of an orthographic projection of the voice coil along the vibration direction.

Further, the elastic supporting member includes a flexible circuit board fixed to the extension part, and a lower diaphragm fixed to the flexible circuit board. The flexible circuit board includes a first surface close to the upper diaphragm and a second surface opposite to the first surface. The lower diaphragm is fixed to the second surface, and the extension part is fixed to the first surface.

Further, the frame includes a plurality of fixing walls locating at corners thereof and extending in a direction away from the upper diaphragm. The magnetic circuit system includes a yoke, a first magnet mounted on the yoke, and a second magnet mounted on the yoke and spaced apart from the first magnet for forming a magnetic gap. The yoke is provided with a plurality of notches at corners thereof for cooperating with the plurality of fixing walls. The fixing walls accommodate in the notches for clamping the yoke.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present disclosure.

FIG. 1 is an isometric view of a speaker in accordance with an exemplary embodiment of the present disclosure.

FIG. 2 is an exploded view of the speaker in FIG. 1.

FIG. 3 is a cross-sectional view of the speaker taken along line A-A in FIG. 1.

### DETAILED DESCRIPTION OF THE EMBODIMENTS

The present disclosure will hereinafter be described in detail with reference to the embodiments. To make the technical problems to be solved, and technical solutions and beneficial effects of the present disclosure more apparent, the present disclosure is described in further detail together with the figures and the embodiments. It should be understood the embodiments described hereby are only to explain the disclosure, not intended to limit the disclosure.

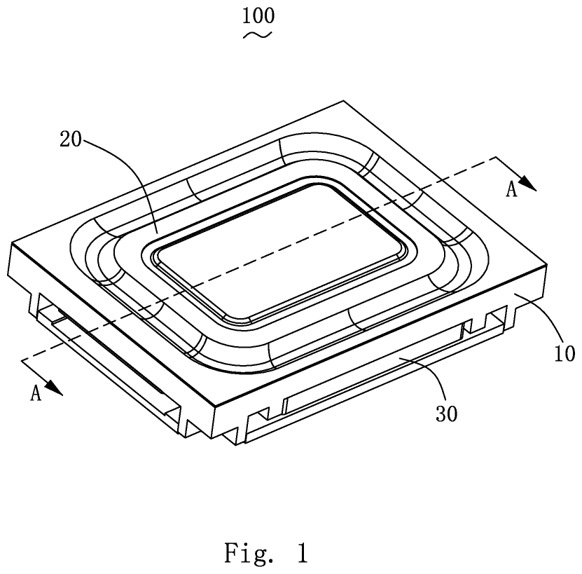

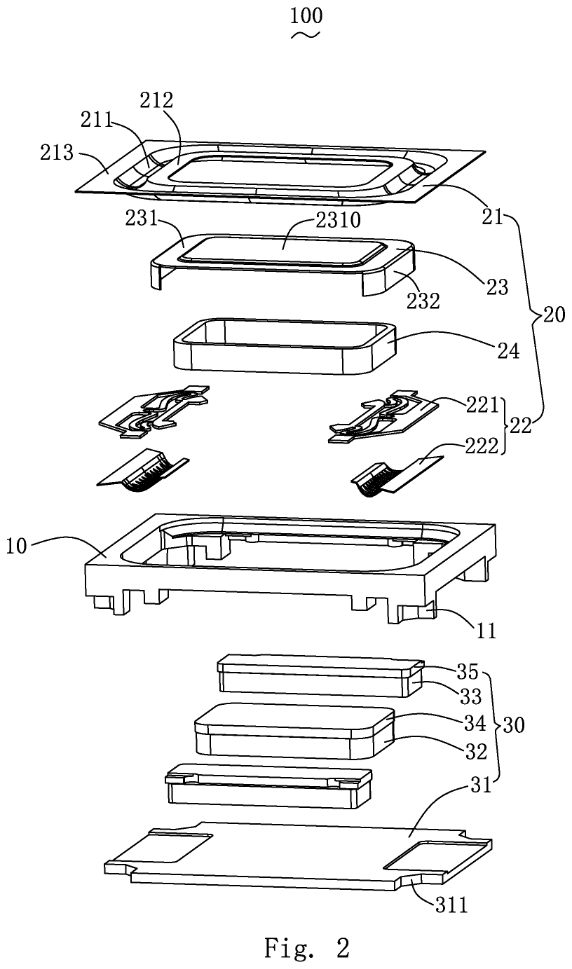

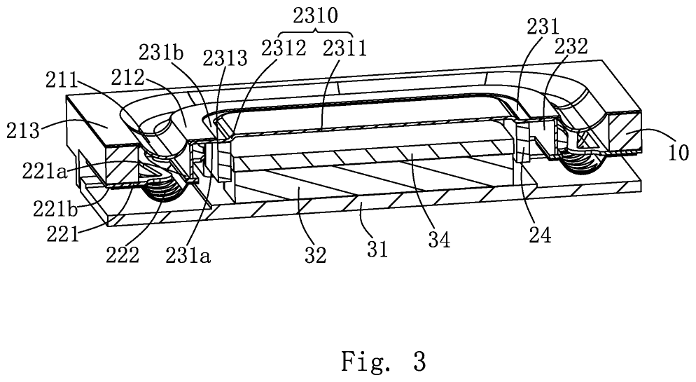

Referring to FIGS. 1-3, the present disclosure discloses a speaker 100 including a frame 10, a vibration system 20 fixed to the frame 10, and a magnetic circuit system 30 fixed to the frame 10 for driving the vibration system 20 to vibrate and emit sound.

The vibration system 20 includes an upper diaphragm 21, an elastic supporting member 22 locating at a side of the upper diaphragm 21 close to the magnetic circuit system 30 and spaced apart from the upper diaphragm 21, a skeleton 23 for connecting the upper diaphragm 21 and the elastic supporting member 22, and a voice coil 24 fixed to the skeleton 23.

The magnetic circuit system 30 includes a yoke 31, a first magnet 32 mounted on the yoke 31, a second magnet 33 mounted on the yoke 31 and spaced apart from the first magnet 32 for forming a magnetic gap, a first pole plate 34 attached on the first magnet 32, and a second pole plate 35 attached on the second magnet 33.

The skeleton 23 includes a main body part 231, and an extension part 232 bending and extending from the main body part 231 in a direction close to the elastic supporting member 22. The elastic supporting member 22 is fixed between the extension part 232 and the frame 10. The upper diaphragm 21 includes a suspension 211, an inner fixing part 212 extending from an inner periphery of the suspension 211, and an outer fixing part 213 extending from an outer periphery of the suspension 211. The inner fixing part 212 is fixed to the skeleton 23. The outer fixing part 213 is fixed to the frame 10. The main body part 231 together with the upper diaphragm 21 separates an internal space of the speaker 100 from an outside space.

Optionally, the main body part 231 includes a lower surface 231a close to the magnetic circuit system 30, and an upper surface 231b opposite to the lower surface 231a. The inner fixing part 212 is fixed to the upper surface 231b. The voice coil 24 is fixed to the lower surface 231a.

Optionally, the main body part 231 is provided with a protrusion 2310 protruding in a direction away from the magnetic circuit system 30. The protrusion 2310 can enhance the structural strength of the main body part 231 for reducing the risk of deformation itself.

Optionally, the main body part 231 includes a first planar portion 2311, a connecting portion 2312 bending and extending from the first planar portion 2311 in a direction close to the magnetic circuit system 30, and a second planar portion 2313 bending and extending from the connecting portion 2312 in a direction away from the first planar portion 2311. The second planar portion 2313 is parallel with the first planar portion 2311. The voice coil 24 is fixed to the second planar portion 2313. The first planar portion 2311 together with the connecting portion 2312 forms the protrusion 2310.

Optionally, an outer edge of an orthographic projection of the protrusion 2310 along a vibration direction of the vibration system 20 coincides with an inner edge of an orthographic projection of the voice coil 24 along the vibration direction. The voice coil 24 locates in the critical area of the protrusion 2310, so that the voice coil 24 drives the position where the structural strength of the main body part 231 is optimal. Alternatively, the main body part 231 may be a whole planar structure without the protrusion 2310.

Optionally, the frame 10 includes a plurality of fixing walls 11 locating at corners thereof and extending in a direction away from the upper diaphragm 21. The yoke 31 is provided with a plurality of notches 311 at corners thereof for cooperating with the plurality of fixing walls 11. The fixing walls 11 accommodate in the notches 311 for clamping the yoke 31 for positioning and fixing the yoke 31 better.

Optionally, the elastic supporting member 22 includes a flexible circuit board 221 fixed to the extension part 232, and a lower diaphragm 222 fixed to the flexible circuit board 221. The flexible circuit board 221 includes a first surface 221a close to the upper diaphragm 21, and a second surface 221b opposite to the first surface 221a. The lower diaphragm 222 is fixed to the second surface 221b. The extension part 232 is fixed to the first surface 221a. The voice coil 24 can be electrically connected with an external circuit via the flexible circuit board 221.

Compared with the related art, the main body part 231 together with the upper diaphragm 21 separates an internal space of the speaker 100 from an outside space. The main body part 231 can serve as a dome, thus an original dome can be omitted. In this way, the height of the space above the magnetic circuit system 30 occupied by the vibration system 20 is only the thickness of the skeleton 23, thereby releasing the height of the space above the magnetic circuit system 30 occupied by the original dome, which can be used for increasing the size of the magnetic circuit system 30. While it avoids effects of the concentricity of the original dome and the skeleton 23 on the vibration system 20 and optimizes the sway of the vibration system 20. Thus, it is beneficial for improving acoustic performances of the speaker 100. In addition, it saves the cost of the original dome and reduces difficulties of manufacturing the vibration system 20.

It is to be understood, however, that even though numerous characteristics and advantages of the embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms where the appended claims are expressed.

What is claimed is:

1. A speaker, comprising:
a frame;
a magnetic circuit system fixed to the frame; and
a vibration system fixed to the frame, comprising:
an upper diaphragm, comprising a suspension, an inner fixing part extending from an inner periphery of the suspension, and an outer fixing part extending from an outer periphery of the suspension;
an elastic supporting member, locating at a side of the upper diaphragm close to the magnetic circuit system and spaced apart from the upper diaphragm;
a skeleton for connecting the upper diaphragm and the elastic supporting member, comprising a main body part, and an extension part bending and extending from the main body part in a direction close to the elastic supporting member; and
a voice coil fixed to the skeleton, wherein,
the elastic supporting member is fixed to the extension part of the skeleton, the inner fixing part of the upper diaphragm is fixed to the skeleton, the outer fixing part of the upper diaphragm is fixed to the frame, the main body part together with the upper diaphragm separates an internal space of the speaker from an outside space.

2. The speaker as described in claim 1, wherein the main body part comprises a lower surface close to the magnetic circuit system, and an upper surface opposite to the lower surface, the inner fixing part is fixed to the upper surface, the voice coil is fixed to the lower surface.

3. The speaker as described in claim 1, wherein the main body part is provided with a protrusion protruding in a direction away from the magnetic circuit system.

4. The speaker as described in claim 3, wherein the main body part comprises a first planar portion, a connecting portion bending and extending from the first planar portion in a direction close to the magnetic circuit system, and a second planar portion bending and extending from the connecting portion in a direction away from the first planar portion, the second planar portion is parallel with the first planar portion, the voice coil is fixed to the second planar portion, the first planar portion together with the connecting portion forms the protrusion.

5. The speaker as described in claim 3, wherein an outer edge of an orthographic projection of the protrusion along a vibration direction of the vibration system coincides with an inner edge of an orthographic projection of the voice coil along the vibration direction.

6. The speaker as described in claim 1, wherein the elastic supporting member comprises a flexible circuit board fixed to the extension part, and a lower diaphragm fixed to the flexible circuit board, the flexible circuit board comprises a first surface close to the upper diaphragm and a second surface opposite to the first surface, the lower diaphragm is fixed to the second surface, the extension part is fixed to the first surface.

7. The speaker as described in claim 1, wherein the frame comprises a plurality of fixing walls locating at corners thereof and extending in a direction away from the upper diaphragm, the magnetic circuit system comprises a yoke, a first magnet mounted on the yoke, and a second magnet mounted on the yoke and spaced apart from the first magnet for forming a magnetic gap, the yoke is provided with a plurality of notches at corners thereof for cooperating with the plurality of fixing walls, the fixing walls accommodate in the notches for clamping the yoke.
